(19) United States
(12) Patent Application Publication
(10) Pub. No.: US 2009/0029047 A1
(43) Pub. Date: Jan. 29, 2009

(54) FILM-FORMING APPARATUS AND FILM-FORMING METHOD

(75) Inventors: Naoki Yoshii, Yamanashi (JP); Koumei Matsuzawa, Toyama (JP); Yasuhiko Kojima, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku, Tokyo (JP)

(21) Appl. No.: 11/909,160

(22) PCT Filed: Mar. 22, 2006
(86) PCT No.: PCT/JP2006/305711

§ 371 Date: Sep. 20, 2007

(30) Foreign Application Priority Data
Mar. 23, 2005 (JP) 2005-082860

(51) Int. Cl. C23C 16/00

(52) U.S. Cl. 427/250; 118/723 R; 118/666

(57) ABSTRACT

Disclosed is a film-forming method characterized by comprising a step for forming a primary Cu film on a substrate by using a divalent Cu source material, and another step for forming a secondary Cu film on the primary Cu film by using a monovalent Cu source material.

### FIELD OF THE INVENTION

The present invention relates to a film forming method and a film forming apparatus for forming a copper (Cu) film on a semiconductor substrate.

### BACKGROUND OF THE INVENTION

Recently, with the realization of high-speed semiconductor devices having highly integrated and miniaturized wiring patterns thereon, Cu is attracting attention as a wiring material, for it has higher conductivity than aluminum as well as high electromigration tolerance.

As a method for forming a Cu film, there has been known a chemical vapor deposition (CVD) method of performing a film formation by reducing and precipitating Cu on a substrate through a pyrolysis reaction of a source gas containing Cu or through a reaction between the source gas containing Cu and a reducing gas. A Cu film formed by this CVD method is suitable for forming fine wiring patterns because it has high coverage as well as high infiltration for a narrow, long and deep pattern. For the CVD formation of the Cu film, a source gas containing monovalent or divalent Cu is utilized (see, for example, Japanese Patent Laid-open Application No. 2000-14420).

Here, if a Ta film, for instance, is used as a barrier film in a CVD process using a source gas containing monovalent Cu, a treatment of adding water and so forth is required to form a Cu film on the Ta film.

However, if water is used as described above, the surface of the Ta film would be oxidized, so that the resistance of the Ta film is increased and it would be difficult to obtain a high adhesiveness between the Cu film and the Ta film. Further, in the CVD process using the source gas containing the monovalent Cu, it is also difficult to form a Cu film on a TaN film or a Ti film as well as the Ta film.

Meanwhile, in a CVD process using a source gas containing divalent Cu, there is little dependency on a base material such as a Ta film, a TaN film or a Ti film, so that it is possible to form a Cu film on the base material, while obtaining a high adhesivity and a high nucleus density of the Cu film.

However, there occurs a problem that the nucleus of the Cu film expands with the growth of the Cu film, making it difficult to obtain a continuous film.

### SUMMARY OF THE INVENTION

It is, therefore, an object of the present invention to provide a film forming method for forming a continuous Cu film having a specific thickness and a high adhesivity to a substrate. Further, it is another object of the present invention to provide a film forming apparatus for performing the film forming method; and a computer readable storage medium for use in controlling the film forming apparatus.

In accordance with a first aspect of the present invention, there is provided a film forming method including the steps of: forming a primary Cu film on a substrate by using a divalent Cu source material; and forming a secondary Cu film on the primary Cu film by using a monovalent Cu source material.

In accordance with the present invention, by forming the primary Cu film on the substrate (base) by using the divalent Cu source material, it is possible to form a dense Cu film having a high adhesivity to the substrate and also having a high kernel density. Further, by forming the secondary Cu film on the primary Cu film by using the monovalent Cu source material, it is possible to grow the Cu film as a continuous film. Accordingly, the present invention has an advantageous effect of forming a continuous flat Cu film having a high adhesivity to the substrate.

Further, though the divalent Cu source material is stable, the film formation can be carried out at a lower substrate temperature if a PEALD (plasma enhanced atomic layer deposition) method is employed in the primary Cu film forming process using the divalent Cu source material (it is already known that the film formation using the monovalent Cu source material can be performed at a low substrate temperature). Thus, it is possible to form a Cu film without causing any (heat) damage on wiring elements formed on the substrate.

Preferably, for example, the PEALD (plasma enhanced atomic layer deposition) method can be employed in the primary Cu film forming process including the steps of: (a) supplying the divalent Cu source material onto the substrate to be adsorbed thereon; (b) stopping the supply of the divalent Cu source material and removing a residual gas from the processing vessel; (c) supplying a reducing gas onto the substrate and converting the reducing gas into radicals by a plasma, thereby reducing the divalent Cu source material adsorbed on the substrate to form a Cu film on the substrate; and (d) stopping the supply of the reducing gas and removing a residual gas from the processing vessel. Further, it is more preferable to respectedly perform the steps (a) to (d) plural times until a Cu film having a desired film thickness is obtained.

Meanwhile, it is preferable to perform the secondary Cu film forming process by way of supplying the monovalent Cu source material onto the substrate along with the reducing gas.

The reducing gas may be one of H₂, NH₃, N₂H₄, NH(CH₃) 2, N₂H₃CH and N₂ or a gaseous mixture of plural gases selected therefrom.

Further, it is preferable that a temperature of the substrate in the primary Cu film forming process and a temperature of the substrate in the secondary Cu film forming process are substantially identical to each other.

Moreover, for example, in the primary Cu film forming process, the Cu film is formed to have a film thickness ranging from 1 nm to 100 nm.

Preferably, the monovalent Cu source material is Cu(hfac)atms or Cu(hfac)TMVS.

Further, preferably, the divalent Cu source material is Cu(dibm)₂, Cu(hfac)₂, or Cu(edmdd)₂.

The above-mentioned film forming method is proper when the substrate has a barrier film made of Ta, TaN, Ti, TiN, W or Wn on the surface thereof. In such case, a Cu film can be formed on the barrier film in the primary Cu film forming process. Further, the above film forming method is proper when the barrier film has an adhesive layer made of Ru, Mg, In, Al, Ag, Co, Nb, B, V, Ir, Pd, Mn, or an Mn oxide (MnO, Mn₃O₄, Mn₂O₃, MnO₂, or Mn₂O₇) on the surface thereof. In such a case, a Cu film having a high adhesivity can be formed on the adhesive layer.

In accordance with a second aspect of the present invention, there is provided a film forming method including the steps of: loading a substrate in a processing vessel; forming a primary Cu film on the substrate by a chemical vapor deposition (CVD) using a divalent Cu source material; and forming a secondary Cu film on the primary Cu film by a CVD using a monovalent Cu source material.

In accordance with the present invention, by forming the primary Cu film on the substrate (base) by using the divalent Cu source material, it is possible to form a dense Cu film having a high adhesivity to the substrate and also having a high kernel density. Further, by forming the secondary Cu film on the primary Cu film by using the monovalent Cu source material, it is possible to grow the Cu film as a continuous film. Accordingly, the present invention has an advantageous effect of forming a continuous flat Cu film having a high adhesivity to the substrate.

In accordance with a third aspect of the present invention, there is provided a film forming apparatus including: a vacuum evacuable processing vessel for accommodating a substrate therein; a first Cu source material supply unit for supplying a monovalent Cu source material into the processing vessel in a gas state; a second Cu source material supply unit for supplying a divalent Cu source material into the processing vessel in a gas state; and a controller for controlling the first and the second Cu source material supply unit such that a primary Cu film is formed on the substrate in the processing vessel by using the divalent Cu source material and, then, a secondary Cu film is formed on the primary Cu film by using the monovalent Cu source material.

In accordance with a fourth aspect of the present invention, there is provided a computer readable storage medium for storing therein a computer executable control program, wherein when executed by a computer for controlling a film forming apparatus for forming a Cu film on a substrate by a CVD method, the control program realizes a control of forming a primary Cu film by using a divalent Cu source material and then forming a secondary Cu film on the primary Cu film by using a monovalent Cu source material.

### BRIEF DESCRIPTION OF THE DRAWINGS

FIG. 1 is a schematic cross sectional view of a film forming apparatus for performing a film forming method in accordance with an embodiment of the present invention;

FIG. 2 sets forth a flowchart to describe a film forming method for forming a Cu film; and

FIGS. 3A and 3B present schematic diagrams to describe the film forming method for forming the Cu film.

### DETAILED DESCRIPTION OF THE EMBODIMENTS

Hereinafter, embodiments of the present invention will be described with reference to the accompanying drawings.

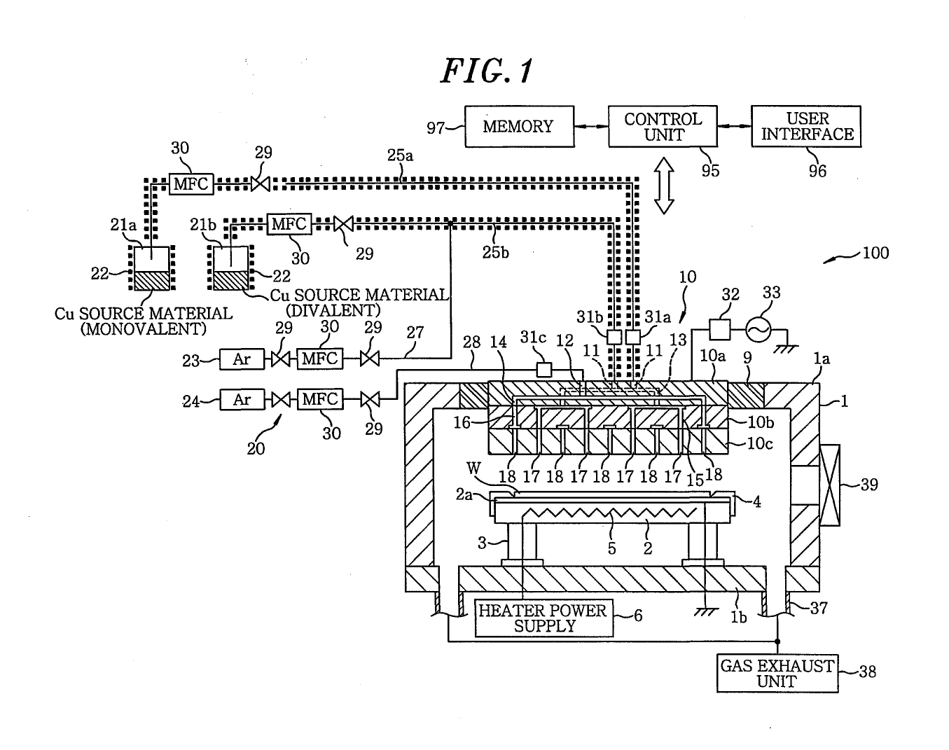

FIG. 1 is a schematic cross sectional view of a film forming apparatus 100 for performing a film forming method in accordance with an embodiment of the present invention.

As shown in FIG. 1, the film forming apparatus 100 has a substantially cylindrical chamber 1 which is hermetically sealed. A susceptor 2 for horizontally supporting a wafer W to be processed thereon is disposed in the chamber 1. The susceptor 2 is supported by a cylindrical support member 3. A guide ring 4 for guiding the wafer W is provided at an outer peripheral portion of the susceptor 2. Further, a heater 5 is embedded in the susceptor 2 and connected to a heater power supply 6. By supplying power to the heater 5 from the heater power supply 6, the wafer W is heated up to a specific temperature. Further, the susceptor 2 has a lower electrode 2a which is grounded.

A shower head 10 is disposed at a ceiling wall portion 1a of the chamber 1 via an insulating member 9. The shower head 10 has an upper block body 10a, an intermediate block body 10b and a lower block body 10c.

The lower block body 10c is provided with first gas injection openings 17 and second gas injection openings 18 through which different types of gases are injected, the first gas injection openings 17 and the second gas injection openings 18 being alternately arranged.

The upper block body 10a is provided with first gas inlet opening 11 and a second gas inlet opening 12 in a top surface thereof. The first gas inlet openings 11 are connected to gas lines 25a and 25b of a gas supply system 20 to be described later, respectively, while the second gas inlet opening 12 is connected to a gas line 28 of the gas supply system 20. Within the upper block body 10a, a number of gas passages 13 branch off from the first gas inlet openings 11 and a plurality of gas passages 14 branch off from the second gas inlet opening 12.

The intermediate block body 10b has gas passages 15 communicating with the gas passages 13 and also has gas passages 16 communicating with the gas passages 14. The gas passages 15 are made to communicate with the gas injection openings 17 of the lower block body 10c, while the gas passages 16 are configured to communicate with the gas injection openings 18 of the lower block body 10c.

The gas supply system 20 includes a first Cu source material supply source 21a for supplying a monovalent Cu source material such as Cu(hfac)atms or Cu(hfac)TMVS; a second Cu source material supply source 21b for supplying a divalent Cu source material such as Cu(dibm)₂, Cu(hfac)₂ or Cu(edmdd)₂; an Ar gas supply source 23 for supplying Ar gas which is a nonreactive gas serving as a carrier gas; and an H₂ gas supply source 24 for supplying H₂ gas which is a reducing gas.

Here, instead of the Ar gas, other nonreactive gas such as N₂ gas, He gas, Ne gas, or the like can be used as the carrier gas. Further, in lieu of the H₂ gas, one of NH₃ gas, N₂H₄ gas, NH(CH₃)₂ gas, N₂H₃CH gas, and N₂ gas or a gaseous mixture of some of them can be employed as the reducing gas.

A first source gas line 25a is connected to the first Cu source material supply source 21a, while a second source gas line 25b is connected to the second Cu source material supply source 21b. A gas line 27 is connected to the Ar gas supply source 23, and a gas line 28 is connected to the H₂ gas supply source 24. The gas line 27 joins the second source gas line 25b.

A mass flow controller 30 is installed on the first source gas line 25a, and a valve 29 is provided downstream of the mass flow controller 30. The second source gas line 25b also has a mass flow controller 30 and a valve 29 installed downstream of the mass flow controller 30. A mass flow controller 30 is also installed on the gas line 27, and valves 29 are provided upstream and downstream of the mass flow controller 30 such that the mass flow controller is located between them. Likewise, the gas line 28 also has a mass flow controller 30 and valves 29, wherein the valves 29 are installed upstream and downstream of the mass flow controller 30 such that the mass flow controller is located between them.

The first Cu source material supply source 21a and the first source gas line 25a are heated by a heater 22 to be maintained at a specific temperature (e.g., 50° C. to 200° C.). Likewise, the second Cu source material supply source 21b and the second source gas line 25b are heated by a heater 22 to be maintained at a certain temperature (e.g., 50° C. to 200° C.).

In this configuration, if a Cu source material is solid at a normal temperature and pressure (Cu(hfac)₂, Cu(dibm)₂), it is possible to sublimate the Cu source material and supply it into the chamber 1 in a gas state by heating the first and the second Cu source material supply source 21a, 21b; and the first and the second source gas line 25a, 25b by means of the heaters 22, while depressurizing the inside of the chamber 1, as will be described later.

Meanwhile, if the Cu source material is a liquid at a normal temperature and pressure (Cu(hfac)atms, Cu(hfac)TMVS, Cu(edmdd)₂), it is possible to evaporate the Cu source material and supply it into the chamber 1 in a gas state by heating the first and the second Cu source material supply source 21a, 21b and the first and the second source gas line 25a, 25b.

The first source gas line 25a extended from the first Cu source material supply source 21a is connected to one of the first gas inlet openings 11 via an insulator 31a, while the second source gas line 25b extended from the second Cu source material supply source 21b is connected to the other one of the first gas inlet openings 11 via an insulator 31b. Meanwhile, the gas line 28 extended from the H₂ gas supply source 24 is connected to the second gas inlet opening 12 via an insulator 31c.

With this configuration, in a primary Cu film forming process, the divalent Cu source material gas supplied from the second Cu source material supply source 21b is carried by the Ar gas supplied from the Ar gas supply source 23 via the gas line 27 and is introduced into the shower head 10 through the first gas inlet opening 11 of the shower head 10 via the second source gas line 25b, to be discharged into the chamber 1 through the first gas injection openings 17 via the gas passages 13 and 15. Further, in FIG. 1, though the Ar gas serving as the carrier gas is supplied from the gas line 27 connected to the second source gas line 25b, it is also possible to install a carrier gas line in the second Cu source material supply source 21b and to supply the Ar gas via the carrier gas line.

Moreover, in a secondary Cu film forming process, the monovalent Cu source material gas supplied from the first Cu source material supply source 21a is introduced into the shower head 10 through the first gas inlet opening 11 of the shower head 10 via the first source gas line 25a, to be discharged into the chamber 1 through the first gas injection openings 17 via the gas passages 13 and 15. Here, it is also possible that the monovalent Cu source material gas is supplied into the chamber 1 by being carried by Ar gas which is supplied from the Ar gas supply source 23 via the gas line 27.

Meanwhile, the H₂ gas supplied from the H₂ gas supply source 24 is introduced into the shower head 10 from the second gas inlet opening 12 of the shower head 10 via the gas line 28, to be discharged into the chamber 1 through the second gas injection openings 18 via the gas passages 14 and 16.

A high frequency power supply 33 is connected to the shower head 10 via a matching unit 32. The high frequency power supply 33 supplies a high frequency power between the shower head 10 and the lower electrode 2a, whereby the H₂ gas supplied into the chamber 1 via the shower head 10 as the reducing gas is converted into a plasma.

Further, a gas exhaust line 37 is connected to a bottom wall 1b of the chamber 1, and a gas exhaust unit 38 is connected to the gas exhaust line 37. By operating the gas exhaust unit 38, the chamber 1 can be depressurized to a specific vacuum level.

Further, a gate valve 39 is provided at a sidewall of the chamber 1. While the gate valve 39 is open, a wafer W is loaded or unloaded between the chamber 1 and the outside.

Each component of the film forming apparatus 100 is connected to and controlled by a control unit (process controller) 95. The control unit 95 includes a user interface 96 having a keyboard for a process manager to input a command to operate (each component of) the film forming apparatus 100, a display for showing an operational status of (each component of) the film forming apparatus 100, and the like; and a memory 97 for storing therein, e.g., control programs (e.g., programs allowing each component of the film forming apparatus 100 to execute processes according to processing conditions) and recipes including processing condition data and the like to be used in realizing various processes, which are performed in the film forming apparatus 100 under the control of the control unit 95.

When a command is received from, e.g., the user interface 96, a necessary recipe is retrieved from the memory 97 and executed by the control unit 95. As a result, a desired process is performed in the film forming apparatus 100 under the control of the control unit 95.

The necessary recipe may be stored in a portable storage medium such as a CD-ROM or a DVD-ROM as well as being stored in a hard disk, a semiconductor memory, or the like. (Here, it is preferable that these storage mediums are set up in a specific location of the memory 97 to be read when necessary.)

Hereinafter, the film forming method for forming a Cu film on a wafer W, which is performed by the film forming apparatus 100 configured as described above, will be explained.

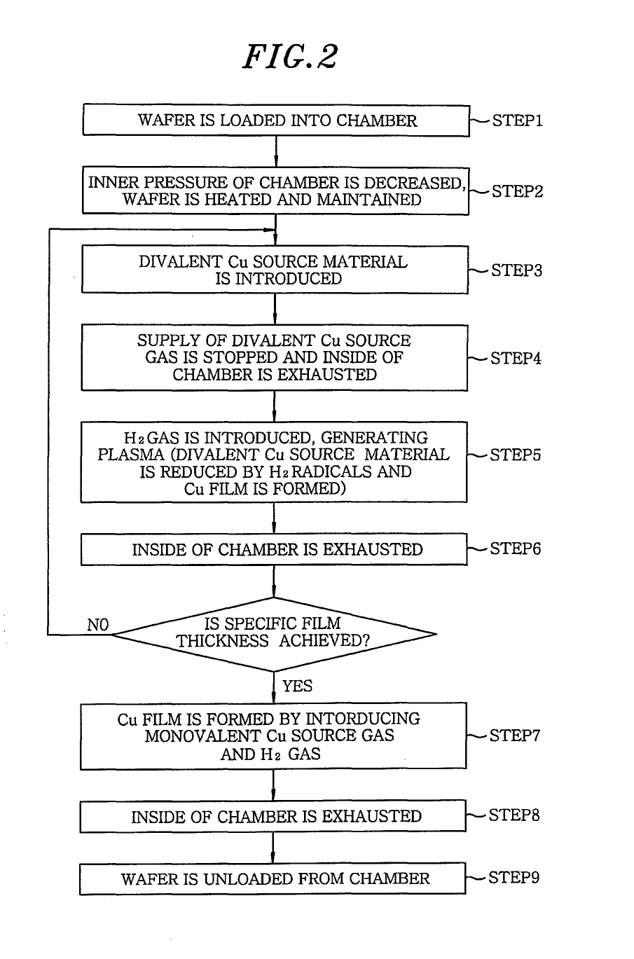

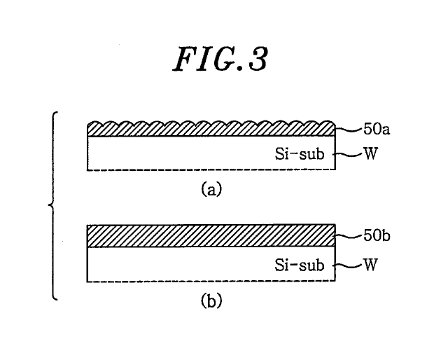

FIG. 2 provides a flowchart to describe a Cu film forming method in accordance with an embodiment of the present invention, and FIGS. 3A and 3B presents schematic diagrams to describe the Cu film forming method.

As shown in FIG. 2, the gate valve 39 is opened first, and a wafer W is loaded into the chamber 1 and mounted on the susceptor 2 (STEP 1).

Subsequently, the gate valve 39 is closed, and the chamber 1 is evacuated by the gas exhaust unit 38 such that the inner pressure of the chamber 1 is maintained within a range of, e.g., 13.33 Pa (0.1 torr) to 1333 Pa (10 torr). The inner pressure of the chamber 1 is kept within this range until a process of STEP8 to be described later is completed. Further, the wafer W is heated by the heater 5 to be maintained at a specific temperature level, e.g., 50° C. to 400° C. and preferably 50° C. to 200° C., where a decomposition of the divalent Cu source material to be supplied into the chamber 1 later (STEP 2) is unlikely to occur.

Then, a primary Cu film forming process using a divalent Cu source material is started. First, the divalent Cu source material such as Cu(hfac)₂ is gasified in the second Cu source material supply source 21b and is introduced into the chamber 1 under the condition that: Cu source gas flow rate: 10 to 1000 mg/min, Ar gas flow rate: 50 to 2000 mL/min (scam), and gas supplying time: 0.1 to 10 seconds. As a result, the divalent Cu source material is adsorbed on the entire surface of the wafer W which is heated up to the specific temperature (STEP3).

Subsequently, the supply of the divalent Cu source gas is stopped, and residual divalent Cu sources gas is exhausted from the chamber 1 (STEP4). At this time, the residual gas may be exhausted while purging the chamber 1 by means of supplying Ar gas therein at a flow rate of, e.g., 50 to 5000 mL/min (scam). Further, H₂ gas or the like which will be supplied into the chamber 1 later may be used as a purge gas.

Thereafter, H₂ gas serving as a reducing gas is fed into the chamber 1 from the H₂ gas supply source 24 at a flow rate of, e.g., 50 to 5000 mL/min (scam). At this time, a high frequency power of, e.g., 50 to 1000 W is applied between the shower head 10 and the lower electrode 2a from the high frequency poser supply 33. As a result, the H₂ gas is converted into a plasma, generating hydrogen radicals (H₂*). By the hydrogen radicals (H₂*), the divalent Cu material adsorbed on the surface of the wafer W is reduced, and, therefore, a primary Cu film is formed on the wafer W (STEP5). The process of STEP5 is continued for, e.g., 0.1 to 10 seconds.

Then, the supply of the H₂ gas and the high frequency power is stopped, and the H₂ gas is exhausted from the chamber 1 (STEP6). In STEP6, the residual gas may be removed by vacuum-exhausted while purging the chamber 1 by means of supplying an Ar gas therein, as in STEP4.

The series of the processes from the STEP3 to STEP6 are repeated until the Cu film formed on the wafer W has a desired film thickness of, e.g., 1 mm to 100 nm. In this way, as shown in FIG. 3A, a dense Cu film (a primary Cu film) 50a having a high adhesivity to the wafer W and a high nucleus density can be obtained.

Conventionally, for example, when a barrier film made of any one of Ta, TaN, Ti, TiN, W and WN is formed on the surface of a wafer W, a treatment of, e.g., adding water is required. However, such a treatment causes an oxidization of the barrier film, resulting in a deterioration of adhesivity or an increase of resistance. In contrast, in the processes from STEP3 to STEP6, no additive is needed, so that a primary Cu film having a fine adhesivity can be formed without causing any damage on the barrier film.

Here, in accordance with the embodiment of the present invention, it is also possible to form a primary Cu film having a high adhesivity on an adhesive layer (metal film) made of any one of Ru, Mg, In, Al, Ag, Co, Nb, B, V, Ir, Pd, Mn, a Mn oxide (MnO, Mn₃O₄, Mn₂O₃, MnO₂, or Mn₂O₇), which is formed on the surface of a barrier film.

After the primary Cu film having the desired film thickness is obtained, a secondary Cu film forming process using a monovalent Cu source material is performed by, e.g., a thermal CVD method. That is, the maintenance temperature of the wafer W is adjusted as required, and a monovalent Cu source material such as Cu(hfac)TMVS is then gasified in the first Cu source material supply source 21a and is introduced into the chamber 1 at a flow rate of, e.g., about 10 to 1000 mg/min. At the same time, H₂ gas serving as a reducing gas is fed into the chamber 1 from the H₂ gas supply source 24 at a flow rate of, e.g., 50 to 1000 mL/min (sccm) until a required film thickness, e.g., about 1 nm to 1000 nm of secondary Cu film is obtained (STEP7). By a reduction reaction between the monovalent Cu source gas and the H₂ gas, the secondary Cu film is allowed to grow on the primary Cu film 50a.

In the process of STEP7, since the secondary Cu film is formed on the previously created primary Cu film, the adhesivity of the secondary Cu film as well as that of the primary Cu film 50a which is obtained after the completion of the process of STEP6 is very high. Thus, as shown in FIG. 3B, a substantially continued (united) secondary Cu film 50b can be obtained.

Since the growth of the kernel of the primary Cu film 50a is not stopped just by repeating the processes of STEP3 to STEP 6, it is difficult to form an even film. By forming the secondary Cu film through performing the process of STEP7, it is possible to form the flat Cu film 50b.

Moreover, in the process of STEP7, the treatment temperature of the wafer W is set to range from 50° C. to 400° C., preferably from 50° C. to 200° C., and this temperature may be set to be different from the wafer treatment temperature in the processes from STEP3 to STEP6. However, if the wafer treatment temperature of STEP7 is set to be equal to that of the processes from STEP3 to STEP 6, no additional time is required to adjust the temperature of the wafer w, so that a throughput can be improved.

After the completion of the process of STEP7, residual gases in the chamber 1 is exhausted (STEP8). In this process of STEP8, the residual gas may be removed by vacuum-exhaust while purging the chamber 1 by mans of supplying Ar gas therein at a flow rate of, e.g., about 50 to 5000 mL/min (sccm). If the residual gases in the chamber 1 are removed, the gate valve 39 is opened, and the wafer W is unloaded from the chamber 1, and the gate valve 39 is closed again (STEP9). At this time, a next wafer W to be processed may be loaded into the chamber 1.

Although the embodiment of the present invention has been described in the above, the present invention is not limited thereto. For example, with respect to the primary Cu film forming process using the divalent Cu source material, there has been exemplified the method of performing the Cu film formation by progressing the reduction reaction of the source material through converting the reducing gas into plasma by the application of the high frequency energy (STEP3 to STEP6). However, depending on the reducibility of the reducing gas, it is also possible to progress the reduction reaction of the source material by a thermal energy generated when heating the wafer W up to the specific temperature by means of the heater 5 or the like disposed in the susceptor 2, without applying the high frequency energy. Further, if it is possible to supply the divalent Cu source material onto the substrate along with the reducing gas without using the above-described PEALD method depending on the property of the divalent Cu source material, another appropriate film forming method can be employed in consideration of a film quality, a throughput, a processing cost, and so forth.

In case Cu source material is a solid at a normal temperature and pressure, a vaporizer may be employed. Specifically, it is possible to set up a configuration in which a solid Cu source material is stored in a tank or the like by being dissolved in a solvent; thus stored liquid source material is sent into a vaporizer provided outside the tank at a specific flow rate via a line by supplying a force-feed gas such as He gas into the tank; the force-fed liquid source material is atomized and vaporized in the vaporizer by using a carrier gas such as a nonreactive gas supplied from a separate line; and the vaporized Cu source material is supplied into the chamber along with the carrier gas. Further, in order to prevent solidification of the vaporized Cu source material, it is preferable that a gas line connected between the vaporizer and the chamber is maintained at a specific temperature by means of a heater or the like.

1. A film forming method comprising:
forming a primary Cu film on a substrate by using a divalent Cu source material; and
forming a secondary Cu film on the primary Cu film by using a monovalent Cu source material.

2. A film forming method comprising:
loading a substrate in a processing vessel;
forming a primary Cu film on the substrate by a chemical vapor deposition (CVD) using a divalent Cu source material; and
forming a secondary Cu film on the primary Cu film by a CVD using a monovalent Cu source material.

3. The film forming method of claim 2, wherein the primary Cu film forming includes:
(a) supplying the divalent Cu source material onto the substrate to be adsorbed thereon;
(b) stopping the supply of the divalent Cu source material and removing a residual gas from the processing vessel;
(c) supplying a reducing gas onto the substrate and converting the reducing gas into radicals by a plasma, thereby reducing the divalent Cu source material adsorbed on the substrate to form a Cu film on the substrate; and
(d) stopping the supply of the reducing gas and removing a residual gas from the processing vessel.

4. The film forming method of claim 2, wherein the secondary Cu film forming includes supplying the monovalent Cu source material onto the substrate along with a reducing gas.

5. The film forming method of claim 3, wherein the reducing gas is one of H₂, NH₃, N₂H₄, NH(CH₃)₂, N₂H₃CH and N₂ or a gaseous mixture of plural gases selected therefrom.

6. The film forming method of claim 2, wherein a temperature of the substrate in the primary Cu film forming and a temperature of the substrate in the secondary Cu film forming are substantially identical to each other.

7. The film forming method of claim 1, wherein in the primary Cu film forming, the Cu film is formed to have a film thickness ranging from 1 nm to 100 nm.

8. The film forming method of claim 1, wherein the monovalent Cu source material is Cu(hfac)atms or Cu(hfac)TMVS.

9. The film forming method of claim 1, wherein the divalent Cu source material is Cu(dibm)₂, Cu(hfac)₂, or Cu(edmdd)₂.

10. The film forming method of claim 1, wherein the substrate has a barrier film on a surface thereof, the barrier film being made of Ta, TaN, Ti, TiN, W or Wn, and in the primary Cu film forming, the Cu film is formed on the barrier film.

11. The film forming method of claim 10, wherein the barrier film has an adhesive layer on a surface thereof, the adhesive layer being made of Ru, Mg, In, Al, Ag, Co, Nb, B, V, Ir, Pd, Mn, or a Mn oxide (MnO, Mn₃O₄, Mn₂O₃, MnO₂, or Mn₂O₇), and in the primary Cu film forming, the Cu film is formed on the adhesive layer.

12. A film forming apparatus comprising:
a vacuum evacuable processing vessel for accommodating a substrate therein;
a first Cu source material supply unit for supplying a monovalent Cu source material into the processing vessel in a gas state;
a second Cu source material supply unit for supplying a divalent Cu source material into the processing vessel in a gas state; and
a controller for controlling the first and the second Cu source material supply unit such that a primary Cu film is formed on the substrate in the processing vessel by using the divalent Cu source material and, then, a secondary Cu film is formed on the primary Cu film by using the monovalent Cu source material.

13. The film forming apparatus of claim 12, further comprising:
a reducing gas supply unit for supplying a reducing gas into the processing vessel; and
a plasma generating unit for converting the supplied reducing gas into a plasma,
wherein the controller controls the first Cu source material supply unit, the second Cu source material supply unit, the reducing gas supply unit and the plasma generating unit such that the primary Cu film is formed by repeating a primary Cu film forming process plural times, the primary Cu film forming process comprising supplying the divalent Cu source material onto the substrate in the processing vessel to be adsorbed thereon; stopping the supply of the divalent Cu source material and evacuating the processing vessel; supplying a reducing gas onto the substrate while converting the reducing gas into radicals by a plasma, thereby reducing the divalent Cu source material adsorbed on the substrate to form the primary Cu film on the substrate; and stopping the supply of the reducing gas and evacuating the processing vessel.

14. The film forming apparatus of claim 12, further comprising a reducing gas supply unit for supplying a reducing gas into the processing vessel,
wherein the controller controls the first Cu source material supply unit, the second Cu source material supply unit and the reducing gas supply unit such that the secondary Cu film is formed by supplying the monovalent Cu source material onto the substrate in the processing vessel along with the reducing gas.

15. The film forming apparatus of claim 12, further comprising a substrate heating unit for heating the substrate in the processing vessel,
wherein the controller controls the substrate heating unit such that the formations of the primary Cu film and the secondary Cu film are performed in a state where the substrate is heated up to a specific temperature.

16. A computer readable storage medium for storing therein a computer executable control program, wherein when executed by a computer for controlling a film forming apparatus for forming a Cu film on a substrate by a CVD method, the control program realizes a control of forming a primary Cu film by using a divalent Cu source material and then forming a secondary Cu film on the primary Cu film by using a monovalent Cu source material.

17. The computer readable storage medium of claim 16, wherein when executed by the computer, the control program realizes a control of repeating the primary Cu film forming process plural times, the primary Cu film forming process comprising supplying the divalent Cu source material onto the substrate in a processing vessel to be adsorbed thereon; stopping the supply of the divalent Cu source material and evacuating the processing vessel; supplying a reducing gas onto the substrate while converting the reducing gas into radicals by a plasma, thereby reducing the divalent Cu source material adsorbed on the substrate to form the Cu film on the substrate; and stopping the supply of the reducing gas and evacuating the processing vessel.

18. The computer readable storage medium of claim 16, wherein when executed by the computer, the control program realizes a control of performing the secondary Cu film forming process of forming the secondary Cu film by supplying the monovalent Cu source material onto the substrate in the processing vessel along with a reducing gas.

19. The film forming method of claim 4, wherein the reducing gas is one of H₂, NH₃, N₂H₄, NH(CH₃)₂, N₂H₃CH and N₂ or a gaseous mixture of plural gases selected therefrom.

20. The film forming method of claim 2, wherein in the primary Cu film forming, the Cu film is formed to have a film thickness ranging from 1 nm to 100 nm.

21. The film forming method of claim 2, wherein the monovalent Cu source material is Cu(hfac)atms or Cu(hfac)TMVS.

22. The film forming method of claim 2, wherein the divalent Cu source material is Cu(dibm)₂, Cu(hfac)₂, or Cu(edmdd)₂.

23. The film forming method of claim 2, wherein the substrate has a barrier film on a surface thereof, the barrier film being made of Ta, TaN, Ti, TiN, W or Wn, and in the primary Cu film forming, the Cu film is formed on the barrier film.

24. The film forming method of claim 23, wherein the barrier film has an adhesive layer on a surface thereof, the adhesive layer being made of Ru, Mg, In, Al, Ag, Co, Nb, B, V, Ir, Pd, Mn, or a Mn oxide (MnO, Mn₃O₄, Mn₂O₃, MnO₂, or Mn₂O₇), and in the primary Cu film forming, the Cu film is formed on the adhesive layer.
